(19) United States
(12) Patent Application Publication
(10) Pub. No.: US 2017/0263546 A1
(43) Pub. Date: Sep. 14, 2017

(54) WIRING BOARD WITH ELECTRICAL ISOLATOR AND BASE BOARD INCORPORATED THEREIN AND SEMICONDUCTOR ASSEMBLY AND MANUFACTURING METHOD THEREOF

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/605,920

(22) Filed: May 25, 2017

Related U.S. Application Data
(63) Continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015.
(60) Provisional application No. 61/949,652, filed on Mar. 7, 2014.

(51) Int. Cl. H01L 23/498; H01L 23/31; H01L 21/48; H01L 23/367; H01L 23/00

(52) U.S. Cl. CPC H01L 23/49838; H01L 23/49811; H01L 23/49827; H01L 23/367; H01L 23/49866; H01L 24/32; H01L 24/49; H01L 21/4857; H01L 21/486; H01L 23/49822; H01L 21/4882; H01L 24/73; H01L 23/3121; H01L 2924/01029; H01L 2924/01022; H01L 2924/01028; H01L 2924/01079; H01L 2924/01047; H01L 2924/0105; H01L 2924/01083; H01L 2924/0132; H01L 2924/19105; H01L 2224/73265; H01L 2224/48091; H01L 2224/48106; H01L 2224/48227; H01L 2224/32225

(57) ABSTRACT

A wiring board includes an electrical isolator laterally surrounded by a base board and a molding compound. The electrical isolator is inserted into a through opening of the base board and has a thickness greater than that of the base board. The molding compound covers the top side of the base board and sidewalls of the electrical isolator, and provides a reliable interface for deposition of a routing circuitry thereon. The base board can serve as an alignment guide for isolator placement or/and provide another routing to enhance electrical routing flexibility for the wiring board.

### CROSS REFERENCE TO RELATED APPLICATIONS

This application is a continuation-in-part of U.S. application Ser. No. 14/621,332 filed Feb. 12, 2015 and a continuation-in-part of U.S. application Ser. No. 14/846,987 filed Sep. 7, 2015, each of which is hereby incorporated by reference.

### FIELD OF THE INVENTION

The present invention relates to a wiring board and, more particularly, to a wiring board having an electrical isolator and a base board incorporated therein, and a semiconductor assembly and a manufacturing method thereof.

### DESCRIPTION OF RELATED ART

High voltage or high current applications such as power module or light emitting diode (LED) often require high performance wiring board for signal interconnection. However, as the power increases, large amount of heat generated by semiconductor chip would degrade device performance and impose thermal stress on the chip. Ceramic material, such as alumina or aluminum nitride which is thermally conductive, electrically insulative and low in CTE (Coefficient of Thermal Expansion), is often considered as a suitable material for such kind of applications. U.S. Pat. Nos. 8,895,998 and 7,670,872 disclose various interconnect structures using ceramic as chip attachment pad material for better reliability. In addition, direct bond copper (DBC) board has become the preferred wiring board for many high power module applications. DBC board typically consists of a ceramic isolator such as Al₂O₃ (aluminium oxide), AlN (aluminium nitride), or Si₃N₄ (silicon nitride) onto which copper layers are double-sided bonded through a high temperature melting and diffusion process. However, the attachment of a thick copper plate to the isolator often requires a very high fusing temperature in a stringent atmosphere, the need of having specific material or conditions to achieve a reliable copper/ceramic interface is tedious, which decreases the manufacturing yield and increases the process complexity. Furthermore, metallization of DBC often requires equal thickness of copper plates fusing at both sides to prevent ceramic plate warpage. While the bottom copper is desirably kept thick and plain as heat spreader, the top copper suffers poor etching resolution due to its thickness which severely limits circuitry routing capability. As a result, conventional DBC boards are not suitable for flip chip or surface mount attachment which is highly desirable for power module assembly.

### SUMMARY OF THE INVENTION

A primary objective of the present invention is to provide a wiring board having a low-CTE and high thermal conductivity isolator embedded in a molding compound so that the chip/board CTE mismatch problem can be resolved and the molding compound provides a reliable interface for deposition of a routing circuitry thereon, thereby improving the mechanical reliability and thermal character of the semiconductor assembly.

Another objective of the present invention is to provide a wiring board in which the isolator is inserted into a through opening of a base board so that the base board can serve as an alignment guide for isolator placement, preventing isolator displacement during molding process, and enhancing electrical routing flexibility for the wiring board.

In accordance with the foregoing and other objectives, the present invention provides a wiring board having electrical isolator and vertical connecting elements incorporated therein, comprising: a base board that includes a top side, a bottom side, a plurality of top contact pads at the top side and a through opening, wherein the through opening has interior sidewalls extending from the top side to the bottom side; an electrical isolator disposed in the through opening of the base board, wherein the electrical isolator has a bottom surface substantially coplanar with the bottom side of the base board and a thickness greater than that of the base board; a molding compound that covers the top side of the base board and extends into a gap between peripheral edges of the electrical isolator and the interior sidewalls of the through opening, wherein the molding compound has an exterior surface substantially coplanar with a top surface of the electrical isolator; a routing circuitry disposed on the exterior surface of the molding compound; and a plurality of vertical connecting elements disposed on the top side of the base board and embedded in the molding compound and electrically coupled to the routing circuitry and the top contact pads of the base board. Further, the present invention also provides a semiconductor assembly that includes a semiconductor device mounted over the top surface of the electrical isolator of the aforementioned wiring board and electrically connected to the routing circuitry.

In another aspect, the present invention provides a method of making a wiring board having electrical isolator incorporated therein, comprising steps of: providing a base board having a top side, a bottom side and a through opening, wherein the through opening has interior sidewalls extending from the top side and the bottom side; inserting an electrical isolator into the through opening of the base board, with peripheral edges of the electrical isolator in close proximity to the interior sidewalls of the through opening and a bottom surface of the electrical isolator substantially coplanar with the bottom side of the base board, wherein the electrical isolator has a thickness greater than that of the electrical isolator; providing a molding compound on the top side of the base board and into a gap between the peripheral edges of the electrical isolator and the interior sidewalls of the through opening, wherein the molding compound has an exterior surface substantially coplanar with a top surface of the electrical isolator; and forming a routing circuitry on the exterior surface of the molding compound.

Unless specifically indicated or using the term “then” between steps, or steps necessarily occurring in a certain order, the sequence of the above-mentioned steps is not limited to that set forth above and may be changed or reordered according to desired design.

The wiring board, the semiconductor assembly and the method of making the same according to the present invention have numerous advantages. For instance, inserting the electrical isolator into the through opening of the base board is particularly advantageous as the base board can ensure the placement accuracy of the electrical isolator or/and provide further routing for the routing circuitry on the molding compound. Depositing the vertical connecting elements on the base board can offer vertical connecting channels for interconnecting the routing circuitry on the molding compound to the base board. Binding the molding compound to the electrical isolator can provide a platform for high resolution circuitries disposed thereon, thereby allowing fine pitch assemblies such as flip chip and surface mount component to be assembled on the wiring board.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of a base board in accordance with the first embodiment of the present invention;

FIGS. 3 and 4 are cross-sectional and top perspective views, respectively, of the structure of FIGS. 1 and 2 further provided with vertical connecting elements in accordance with the first embodiment of the present invention;

FIGS. 5 and 6 are cross-sectional and top perspective views, respectively, of the structure of FIGS. 3 and 4 further provided with a through opening in the base board in accordance with the first embodiment of the present invention;

FIGS. 7 and 8 are cross-sectional and top perspective views, respectively, of the structure of FIGS. 5 and 6 further provided with an electrical isolator in accordance with the first embodiment of the present invention;

FIG. 9 is a cross-sectional view of structure of FIG. 7 further provided with a molding compound in accordance with the first embodiment of the present invention;

FIG. 10 is a cross-sectional view of structure of FIG. 9 after removal of the upper portion of the molding compound in accordance with the first embodiment of the present invention;

FIGS. 11 and 12 are cross-sectional and top perspective views, respectively, of the structure of FIG. 10 further provided with a routing circuitry and a bottom plated layer to finish the fabrication of a wiring board in accordance with the first embodiment of the present invention;

FIGS. 13 and 14 are cross-sectional and top perspective views, respectively, of the structure of FIGS. 11 and 12 further provided with a semiconductor device in accordance with the first embodiment of the present invention;

FIG. 15 is a cross-sectional view of another aspect of the wiring board in accordance with the first embodiment of the present invention;

FIG. 16 is a cross-sectional view of yet another aspect of the wiring board in accordance with the first embodiment of the present invention;

FIG. 17 is a cross-sectional view of yet another aspect of the wiring board in accordance with the first embodiment of the present invention;

FIG. 18 is a cross-sectional view of yet another aspect of the wiring board in accordance with the first embodiment of the present invention;

FIG. 19 is a cross-sectional view of structure of FIG. 11 further provided with a top dielectric layer in accordance with the second embodiment of the present invention;

FIG. 20 is a cross-sectional view of structure of FIG. 19 further provided with top conductive traces to finish the fabrication of a wiring board in accordance with the second embodiment of the present invention;

FIG. 21 is a cross-sectional view of the structure of FIG. 20 further provided with a semiconductor device in accordance with the second embodiment of the present invention;

FIG. 22 is a cross-sectional view of another wiring board in accordance with the third embodiment of the present invention;

FIG. 23 is a cross-sectional view of another aspect of the wiring board in accordance with the third embodiment of the present invention;

FIG. 24 is a cross-sectional view of the structure of FIG. 22 further provided with a semiconductor device and passive components in accordance with the third embodiment of the present invention;

FIG. 25 is a cross-sectional view of the structure of FIG. 22 further provided with semiconductor devices, passive components and an encapsulant in accordance with the third embodiment of the present invention;

FIG. 26 is a cross-sectional view of another aspect of the wiring board further provided with a semiconductor device, passive components and an encapsulant in accordance with the third embodiment of the present invention;

FIG. 27 is a cross-sectional view of yet another aspect of the wiring board further provided with a semiconductor device, passive components and an encapsulant in accordance with the third embodiment of the present invention;

FIG. 28 is a cross-sectional view of yet another wiring board in accordance with the fourth embodiment of the present invention;

FIG. 29 is a cross-sectional view of yet another wiring board in accordance with the fifth embodiment of the present invention;

FIG. 30 is a cross-sectional view of structure of FIG. 29 further provided with a bottom dielectric layer in accordance with the sixth embodiment of the present invention; and

FIG. 31 is a cross-sectional view of structure of FIG. 30 further provided with bottom conductive traces to finish the fabrication of a wiring board in accordance with the sixth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

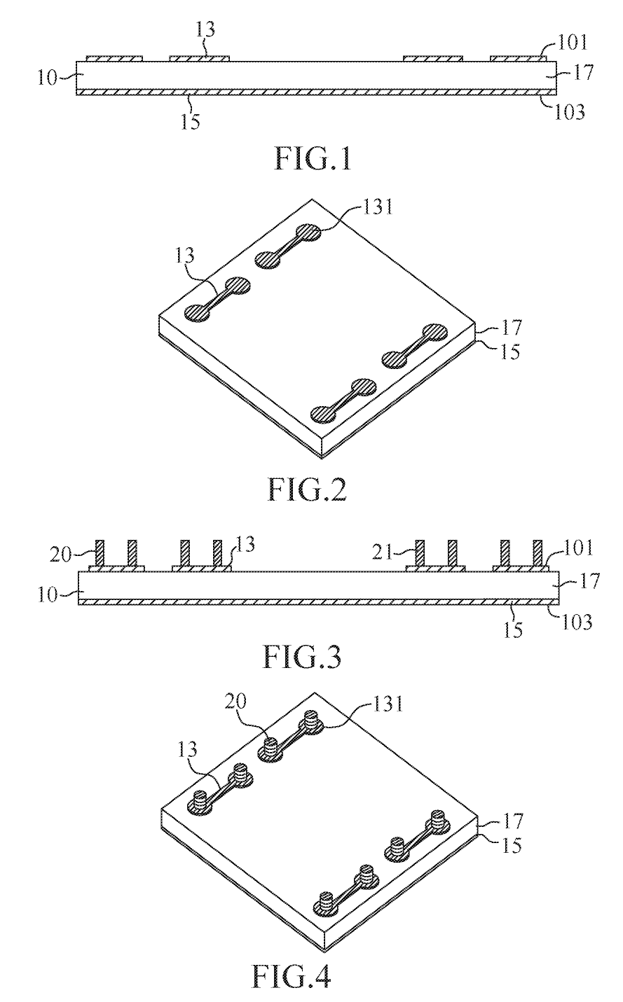

FIGS. 1-12 are schematic views showing a method of making a wiring board that includes an electrical isolator, a base board, a plurality of vertical connecting elements, a molding compound, a routing circuitry and a bottom plated layer in accordance with the first embodiment of the present invention.

FIGS. 1 and 2 are cross-sectional and top perspective views, respectively, of a base board 10. In this embodiment, the base board 10 includes a top wiring layer 13 at its top side 101, a bottom metal layer 15 at its bottom side 103, and an insulating layer 17 between the top wiring layer 13 and the bottom metal layer 15. The insulating layer 17 can be made of ceramic, glass, epoxy resin, molding compound, glass-epoxy, polyimide, or the like. The top wiring layer 13 typically is a patterned copper layer and includes a plurality of top contact pads 131, as shown in FIG. 2. The bottom metal layer 15 is unpatterned copper layer and completely covers the insulating layer 17 from below.

FIGS. 3 and 4 are cross-sectional and top perspective views, respectively, of the structure provided with vertical connecting elements 20 on the top side 101 of the base board 10. The vertical connecting elements 20 can be made of Cu, Sn, Ti, Ni, Au, Ag, Sn alloy or other suitable electrically conductive materials. The Sn alloy may contain Ag, Cu, Bi, or combinations thereof. By vacuum sputtering, electroplating, soldering, wire bonding, welding or other suitable methods, metal posts, solder balls, bonding wires or their combination can be deposited on the top wiring layer 13 of the base board 10 to serve as the vertical connecting elements 20. Additionally, the vertical connecting elements 20 can also be formed in a bonded structure. For example, the vertical connecting elements 20 may be bonded solder bumps, or bonded copper posts with a joining solder layer. Solder described here may include lead (e.g., Sn/Pb) or may be lead-free (e.g., Au/Sn or Sn/Ag/Cu). In this illustration, the vertical connecting elements 20 are metal posts 21 formed by electroplating, and are electrically connected to the top contact pads 131 of the top wiring layer 13.

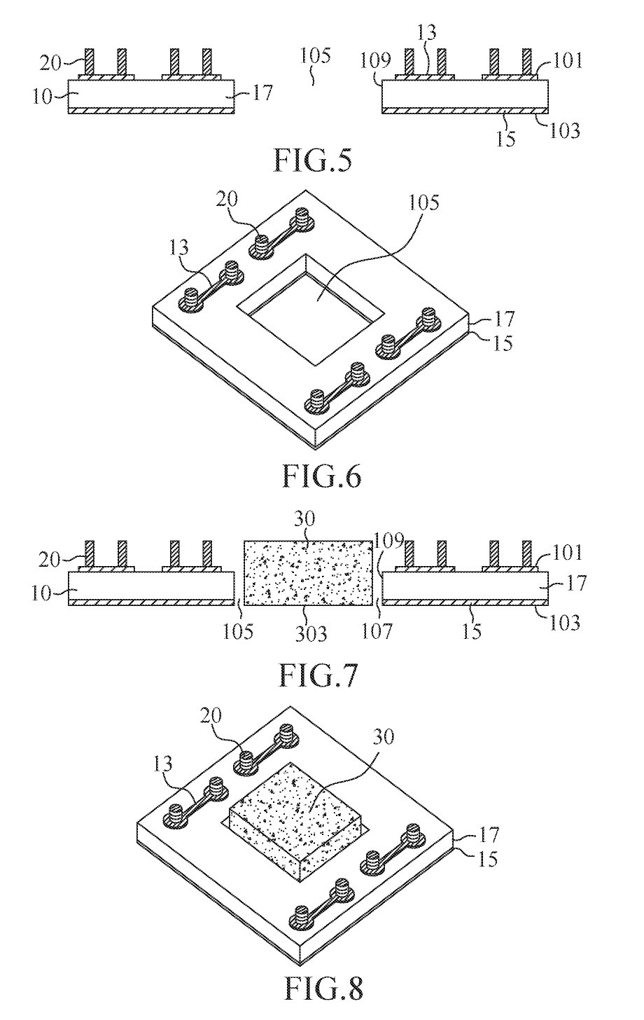

FIGS. 5 and 6 are cross-sectional and top perspective views, respectively, of the structure formed with a through opening 105 in the base board 10. The through opening 105 has interior sidewalls 109 extending through the base board 10 from the top side 101 to the bottom side 103 thereof. The through opening 105 can be formed by numerous techniques, such as punching, drilling or laser cutting.

FIGS. 7 and 8 are cross-sectional and top perspective views, respectively, of the structure with an electrical isolator 30 inserted into the through opening 105 of the base board 10. The electrical isolator 30 typically has high elastic modulus and low coefficient of thermal expansion (for example, 2×10⁻⁶ K⁻¹ to 10×10⁻⁶ K⁻¹), such as ceramic, silicon, glass or other thermally conductive and electrically insulating materials. In this embodiment, the electrical isolator 30 is a ceramic slug having a thickness substantially equal to the combined thickness of the base board 10 and the vertically connecting elements 20. The electrical isolator 30 is placed in the through opening 105 of the base board 10, with the bottom side 103 of the base board 10 substantially coplanar with a bottom surface 303 of the electrical isolator 30. As the through opening 105 has a dimension larger than the electrical isolator 30, a gap 107 is left in the through opening 105 between the interior sidewalls 109 of the base board 10 and the peripheral edges of the electrical isolator 30. The gap 107 laterally surrounds the electrical isolator 30 and is laterally surrounded by the base board 10. In some cases, the interior sidewalls 109 of the base board 10 may be used as an alignment guide to ensure the placement accuracy of the electrical isolator 30. Accordingly, the electrical isolator 30 can be accurately confined at a predetermined location, with the peripheral edges of the electrical isolator 30 in close proximity to the interior sidewalls 109 of the through opening 105 of the base board 10.

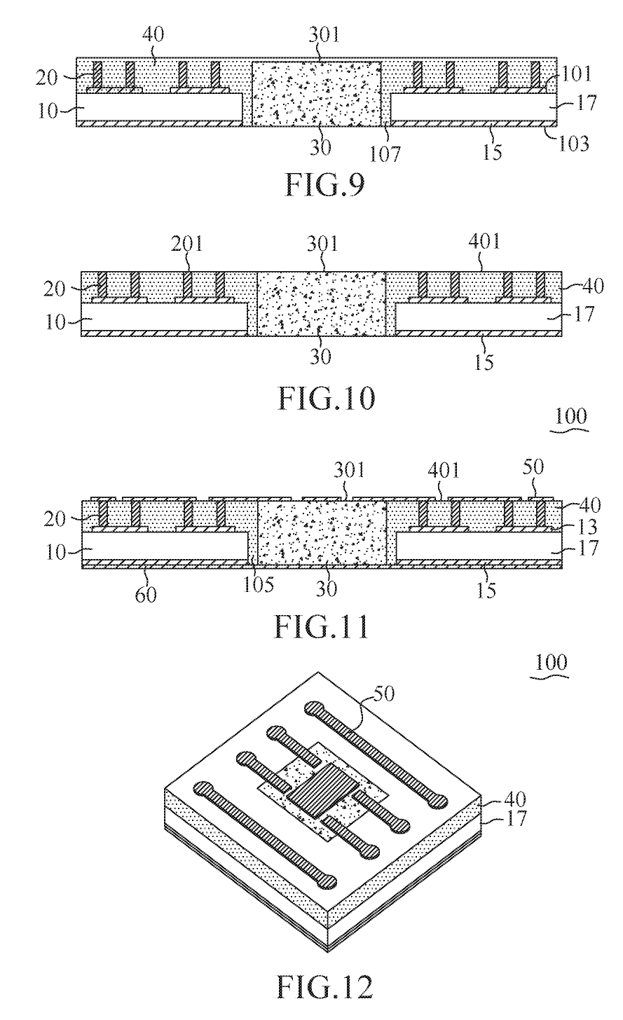

FIG. 9 is a cross-sectional view of the structure provided with a molding compound 40. The molding compound 40 can be deposited by applying a molding material on the top side 101 of the base board 10 as well as the top surface 301 of the electrical isolator 30 and into the gap 107 between the base board 10 and the electrical isolator 30. The molding material can be applied by paste printing, compressive molding, transfer molding, liquid injection molding, spin coating, or other suitable methods. Then, a thermal process (or heat-hardened process) is applied to harden the molding material and to transform it into a solid molding compound. As a result, the molding compound 40 covers the base board 10, the vertical connecting elements 20 and the electrical isolator 30 from above, and laterally covers and surrounds and conformally coats the interior sidewalls 109 of the base board 10 and sidewalls of the vertical connecting elements 20 and the electrical isolator 30.

The molding compound 40 typically includes binder resins, fillers, hardeners, diluents, and additives. There is no particular limit to the binder resin that can be used in accordance with the present invention. For example, the binder resin may be at least one selected from the group consisting of an epoxy resin, a phenol resin, a polyimide resin, a polyurethane resin, a silicone resin, a polyester resin, an acrylate, bismaleimide (BMI), and equivalents thereof. The binder resin provides intimate adhesion between an adherent and the filler. The binder resin also serves to elicit thermal conductivity through chain-like connection of the filler. The binder resin may also improve physical and chemical stability of the molding compound 40.

Additionally, there is no particular limit to the filler that can be used in accordance with the present invention. For example, a thermally conductive filler may be selected from the group consisting of aluminum oxide, aluminum nitride, silicon carbide, tungsten carbide, boron carbide, silica and equivalents thereof. More specifically, the molding compound 40 may become thermally conductive or low CTE if suitable fillers are dispersed therein. For example, aluminum nitride (AlN) or silicon carbide (SiC) has relatively high thermal conductivity, high electrical resistance, and a relatively low coefficient of thermal expansion (CTE). Accordingly, when the molding compound 40 employs these kinds of materials as fillers, the molding compound 40 would exhibit improved heat dissipation performance, electrical isolation performance and shows inhibition of delamination or cracking of circuitry or interfaces due to low CTE. The maximum particle size of the thermally conductive filler may be 25 μm or less. The content of the filler may be in the range of 10 to 90% by weight. If the content of the thermally conductive filler is less than 10% by weight, this may result in insufficient thermal conductivity and excessively low viscosity. Low viscosity means that it may be difficult to handle and control the process due to excessively easy outflow of the resin from the tool during dispensing or molding process. On the other hand, if the content of the filler is higher than 90% by weight, this may result in decreased adhesive strength and excessively high viscosity of the molding material. High viscosity of the molding material results in poor workability due to no outflow of the material from the tool, during the dispensing or molding process. Additionally, the molding compound 40 may include more than one type of fillers. For example, the second filler may be polytetrafluoroethylene (PTFE) so as to further improve electrical isolation property of the molding compound 40. In any case, the molding compound 40 preferably has an elastic modulus larger than 1.0 GPa and a linear coefficient of thermal expansion in a range from about 5×10⁻⁶ K⁻¹ to about 15×10⁻⁶ K⁻¹.

FIG. 10 is a cross-sectional view of the structure after removal of the upper portion of the molding compound 40. The upper portion of the molding compound 40 can be removed by a planarization process to expose the vertical connecting elements 20 and the electrical isolator 30 from above. The planarization process can be a lapping/grinding process, or a chemical-mechanical polishing (CMP) process. After planarization, the molding compound 40 has a thickness in a range of 0.05 to 1 mm (preferably 0.1 to 0.4 mm), and has an exterior surface 401 substantially coplanar with the top side 201 of the vertical connecting elements 20 and the top surface 301 of the electrical isolator 30.

FIGS. 11 and 12 are partial cross-sectional and top perspective views, respectively, of the structure provided with a routing circuitry 50 by metal pattern deposition. The top surface of the structure can be metallized to form an electrically conductive layer (typically a copper layer) as a single layer or multiple layers by numerous techniques, such as electroplating, electroless plating, evaporating, sputtering or their combinations. The electrically conductive layer can be made of Cu, Ni, Ti, Au, Ag, Al, their combinations, or other suitable electrically conductive material. Typically, a seeding layer is formed on the topmost surface of the structure prior to the electrically conductive layer is electroplated to a desirable thickness. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range described above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, a photoresist layer (not shown) is formed over the seeding layer. The photoresist layer may be formed by a wet process, such as a spin-on process, or by a dry process, such as lamination of a dry film. After the photoresist layer is formed, the photoresist layer is patterned to form openings, which are then filled with plated metal such as copper to form the routing circuitry 50. After metal plating, the exposed seeding layer is then removed by etching process to form electrically isolated conductive traces as desired. In this illustration, the routing circuitry 50 is a patterned metal layer and laterally extends on the exterior surface 401 of the molding compound 40 and the top surface 301 of the electrical isolator 30, and contacts and is electrically coupled to the vertical connecting elements 20 and thermally conductible to the electrical isolator 30. Optionally, the bottom surface of the structure may also be metallized to form a bottom plated layer 60 that contacts and completely covers the bottom metal layer 15 of the base board 10, the electrical isolator 30 and the molding compound 40 from below.

Accordingly, as shown in FIGS. 11 and 12, a wiring board 100 is accomplished and includes a base board 10, vertical connecting elements 20, an electrical isolator 30, a molding compound 40, a routing circuitry 50 and a bottom plated layer 60. The electrical isolator 30 is disposed in a through opening 105 of the base board 10, and has a larger thickness than the base board 10. The vertical connecting elements 20 are disposed on and electrically coupled to a top wiring layer 13 of the base board 10. The molding compound 40 covers and surrounds sidewalls of the vertical connecting elements 20 and the electrical isolator 30, and provides mechanical bonds between the interior sidewalls 109 of the base board 10 and the peripheral edges of the electrical isolator 30. The routing circuitry 50 laterally extend on the exterior surface 401 of the molding compound 40 and the top surface 301 of the electrical isolator 30 to provide horizontal routing, and are electrically coupled to the vertical connecting elements 20 that provide vertical routing. As a result, the routing circuitry 50 can be electrically connected to the top wiring layer 13 of the base board 10 through the vertical connecting elements 20. The bottom plated layer 60 is a continuous unpatterned metal layer disposed underneath the base board 10 and the electrical isolator 30, and provides a larger thermal dissipation surface area than the electrical isolator 30.

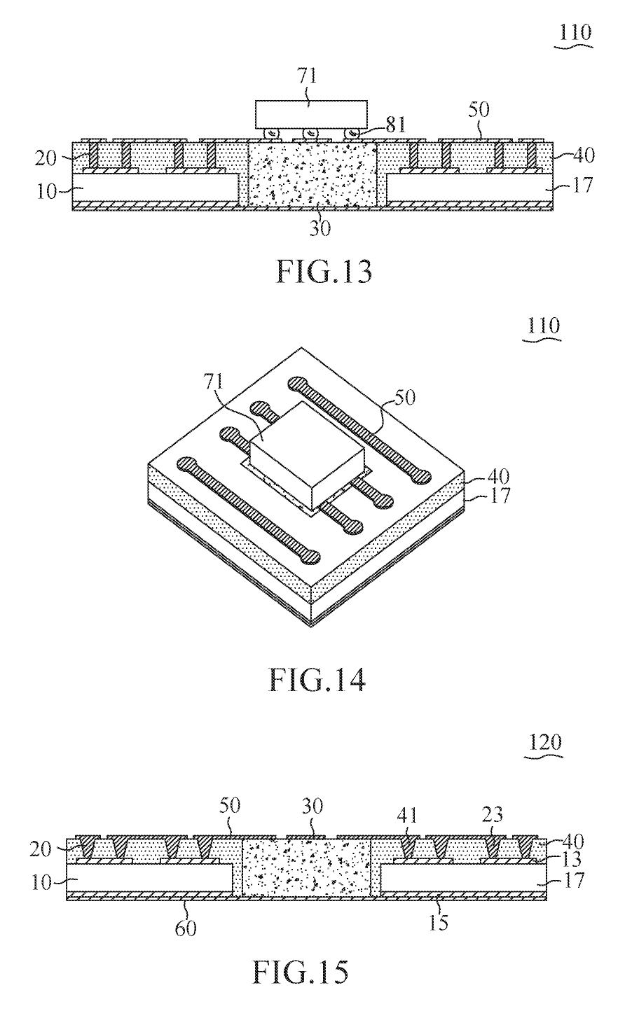

FIGS. 13 and 14 are cross-sectional and top perspective views, respectively, of a semiconductor assembly 110 with a semiconductor device 71 electrically connected to the wiring board 100 illustrated in FIGS. 11 and 12. The semiconductor device 71, illustrated as a chip, is flip-chip mounted over the top surface of the electrical isolator 30 and electrically coupled to the routing circuitry 50 via conductive bumps 81.

FIG. 15 is a cross-sectional view of another aspect of the wiring board according to the first embodiment of the present invention. The wiring board 120 is similar to that illustrated in FIG. 11, except that it includes metal filled vias 23 as the vertical connecting elements 20. The metal filled vias 23 are formed by metal deposition in via openings 41 of the molding compound 40 and contact the top wiring layer 13 of the base board 10.

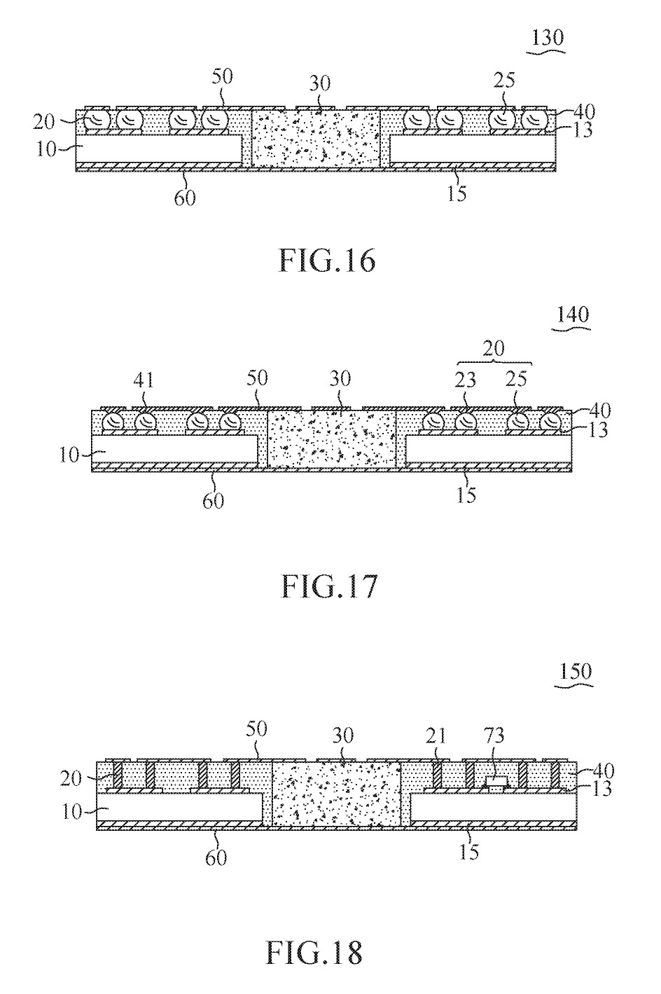

FIG. 16 is a cross-sectional view of yet another aspect of the wiring board according to the first embodiment of the present invention. The wiring board 130 is similar to that illustrated in FIG. 11, except that it includes conductive balls 25 such as copper balls as the vertical connecting elements 20.

FIG. 17 is a cross-sectional view of yet another aspect of the wiring board according to the first embodiment of the present invention. The wiring board 140 is similar to that illustrated in FIG. 11, except that it includes the combination of metal filled vias 23 and conductive balls 25 as the vertical connecting elements 20. The metal filled vias 23 are formed by metal deposition in via openings 41 of the molding compound 40 and contact the conductive balls 25.

FIG. 18 is a cross-sectional view of yet another aspect of the wiring board according to the first embodiment of the present invention. The wiring board 150 is similar to that illustrated in FIG. 11, except that it further includes a passive component 73 embedded in the molding compound 40. The passive component 73 is electrically coupled to the top wiring layer 13 of the base board 10, and thereby is electrically connected to the routing circuitry 50 through the vertical connecting elements 20.

### Embodiment 2

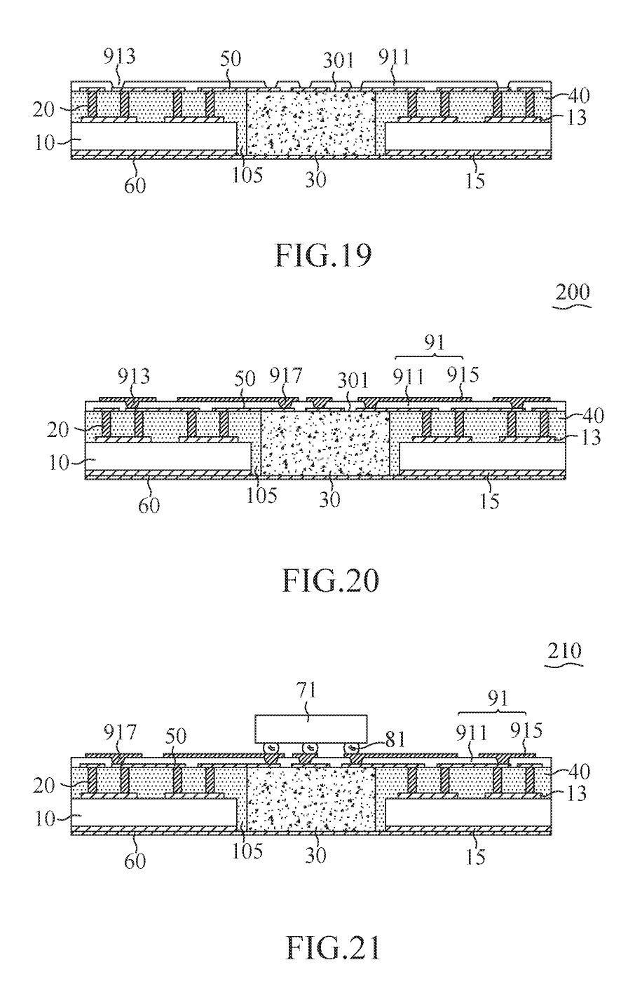

FIGS. 19-20 are schematic views showing a method of making a wiring board having a top buildup circuitry in accordance with the second embodiment of the present invention.

For purposes of brevity, any description in Embodiment 1 is incorporated herein insofar as the same is applicable, and the same description need not be repeated.

FIG. 19 is a cross-sectional view of the structure of FIG. 11 further provided with a top dielectric layer 911 on the routing circuitry 50 as well as the electrical isolator 30 and the molding compound 40 and via openings 913 in the top dielectric layer 911. The top dielectric layer 911 is deposited typically by lamination or coating, and contacts and covers and extends laterally on the electrical isolator 30, the molding compound 40 and the routing circuitry 50 from above. The top dielectric layer 911 typically has a thickness of 50 microns, and can be made of epoxy resin, glass-epoxy, polyimide, or the like. After the deposition of the top dielectric layer 911, the via openings 913 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The via openings 913 extend through the top dielectric layer 911 and are aligned with selected portions of the routing circuitry 50.

Referring now to FIG. 20, top conductive traces 915 are formed on the top dielectric layer 911 by metal deposition and metal patterning process. The top conductive traces 915 extend from the routing circuitry 50 in the upward direction, fill up the via openings 913 to form metallized vias 917 in direct contact with the routing circuitry 50, and extend laterally on the top dielectric layer 911. As a result, the top conductive traces 915 can provide horizontal signal routing in both the X and Y directions and vertical routing through the via openings 913 and serve as electrical connections for the routing circuitry 50.

The top conductive traces 915 can be deposited as a single layer or multiple layers by any of numerous techniques, such as electroplating, electroless plating, evaporating, sputtering, or their combinations. For instance, they can be deposited by first dipping the structure in an activator solution to render the top dielectric layer 911 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the top conductive traces 915 by any of numerous techniques such as wet etching, electro-chemical etching, laser-assist etching, or their combinations, with an etch mask (not shown) thereon that defines the top conductive traces 915.

Accordingly, as shown in FIG. 20, a wiring board 200 is accomplished and includes a base board 10, vertical connecting elements 20, an electrical isolator 30, a molding compound 40, a routing circuitry 50, a bottom plated layer 60 and a top buildup circuitry 91. In this illustration, the top buildup circuitry 91 is a multi-layered buildup circuitry and includes a top dielectric layer 911 and top conductive traces 915. As a result, the combination of the top wiring layer 13, the vertical connecting elements 20 and the top buildup circuitry 91 can provide routing/interconnection for a semiconductor device to be assembled on the wiring board 200.

FIG. 21 is a cross-sectional view of a semiconductor assembly 210 with a semiconductor device 71 electrically connected to the wiring board 200 illustrated in FIG. 20. The semiconductor device 71, illustrated as a chip, is aligned with the electrical isolator 30 and flip-chip mounted over the top buildup circuitry 91 and electrically coupled to the top conductive traces 915 via conductive bumps 81. As the top buildup circuitry 91 is thermally conductible to the electrical isolator 30 through the metallized vias 917 as heat pipes, the heat generated from the semiconductor device 71 can be transferred to the electrical isolator 30 and further be spread out.

### Embodiment 3

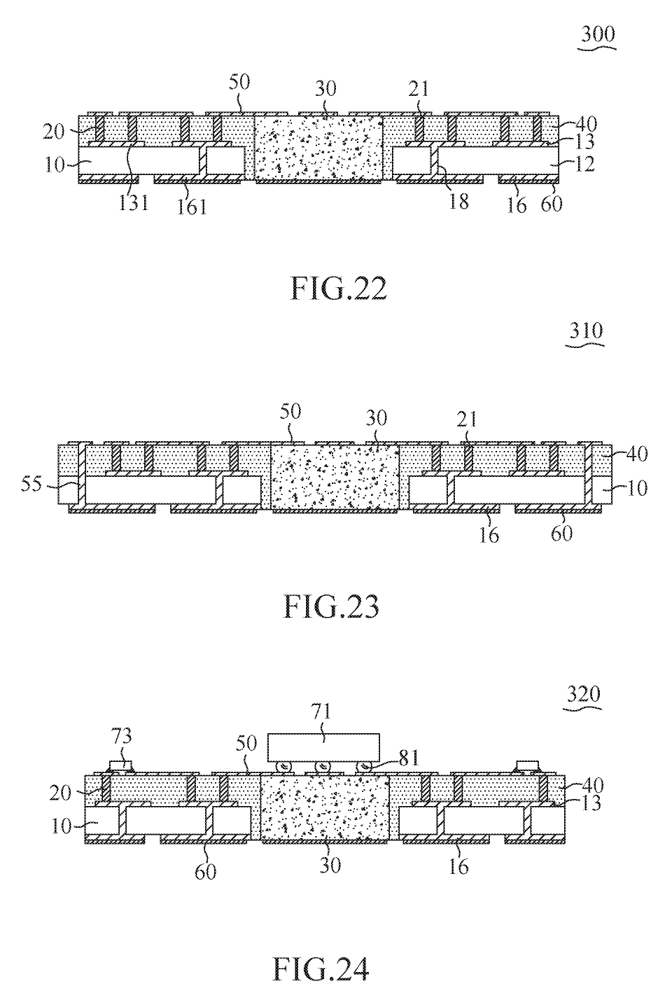

FIG. 22 is a cross-sectional view of a wiring board in which the routing circuitry is electrically connected to a bottom wiring layer of the base board in accordance with the third embodiment of the present invention.

For purposes of brevity, any description in Embodiments above is incorporated herein insofar as the same is applicable, and the same description need not be repeated.

The wiring board 300 is similar to that illustrated in FIG. 11, except that the base board 10 is a multi-layer circuit board and the bottom plated layer 60 is a patterned metal layer. In this illustration, the base board 10 includes a core layer 12, a top wiring layer 13, a bottom wiring layer 16 and metallized through vias 18. The top wiring layer 13 and the bottom wiring layer 16 respectively extend laterally on the two sides of the core layer 12. The top wiring layer 13 includes top contact pads 131 for electrical connection with the vertical connecting elements 20, whereas the bottom wiring layer 16 includes bottom contact pads 161 for next-level electrical connection. The metallized through vias 18 extend through the core layer 12 to provide electrical connections between the top contact pads 131 and the bottom contact pads 161. As a result, the routing circuitry 50 on the top surface of the electrical isolator 30 and the exterior surface of the molding compound 40 can be electrically connected to the bottom wiring layer 16 of the base board 10 through the vertical connecting elements 20, the top wiring layer 13 and the metallized through vias 18. In this embodiment, the base board 10 is not limited to the multi-layer circuit board, and also may be a co-fired ceramic, a molded interconnect substrate (MIS) or a build-up substrate.

FIG. 23 is a cross-sectional view of another aspect of the wiring board according to the third embodiment of the present invention. The wiring board 310 is similar to that illustrated in FIG. 22, except that it further includes metallized through holes 55 in direct contact with the routing circuitry 50 and the bottom wiring layer 16. The metallized through holes 55 extend through the base board 10 and the molding compound 40, and provide electrical connection between the routing circuitry 55 and the bottom wiring layer 16 of the base board 10.

FIG. 24 is a cross-sectional view of a semiconductor assembly 320 with a semiconductor device 71 and passive components 73 electrically connected to the wiring board 300 illustrated in FIG. 22. The semiconductor device 71 is flip-chip mounted over the top surface of the electrical isolator 30 and electrically coupled to the routing circuitry 50 via conductive bumps 81. The passive components 73 are mounted over the top side of the molding compound 40 and electrically coupled to the routing circuitry 50.

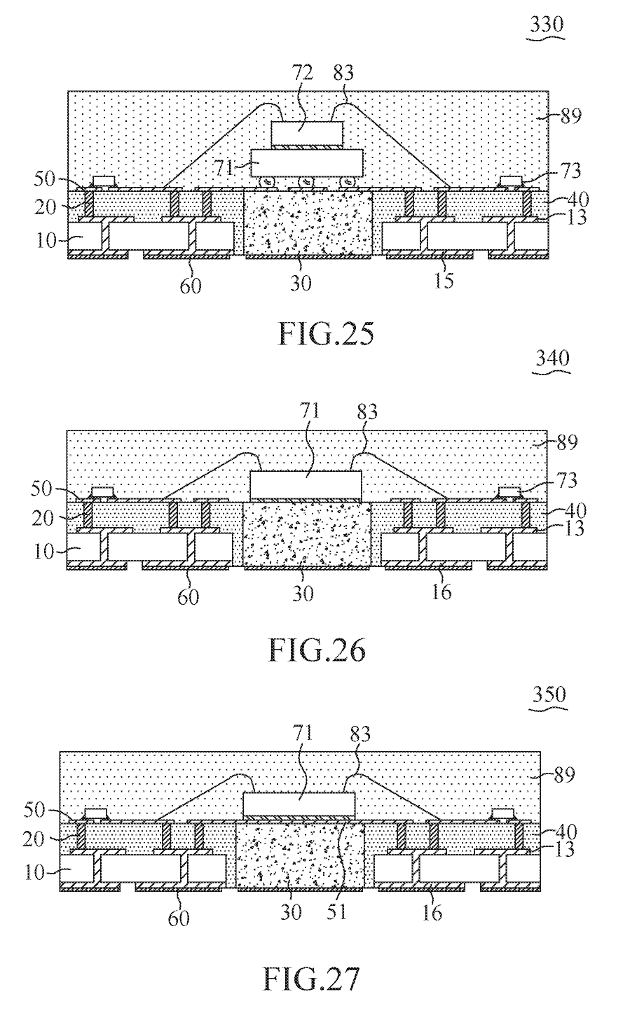

FIG. 25 is a cross-sectional view of another aspect of the semiconductor assembly according to the third embodiment of the present invention. The semiconductor assembly 330 is similar to that illustrated in FIG. 24, except that it further includes an additional semiconductor device 72 and an encapsulant 89. The additional semiconductor device 72 is mounted on the semiconductor device 71 and electrically coupled to the routing circuitry 50 through bonding wires 83. The encapsulant 89 covers the semiconductor devices 71, 72, the passive components 73 and the bonding wires 83 from above.

FIG. 26 is a cross-sectional view of yet another aspect of the semiconductor assembly according to the third embodiment of the present invention. The semiconductor assembly 340 is similar to that illustrated in FIG. 24, except that (i) the routing circuitry 50 does not laterally extend onto the electrical isolator 30, (ii) the semiconductor device 71 is mounted over the electrical isolator 30 and electrically coupled to the routing circuitry 50 through bonding wires 83, and (iii) an encapsulant 89 is further provided to cover the semiconductor device 71, the passive components 73 and bonding wires 83 from above.

FIG. 27 is a cross-sectional view of yet another aspect of the semiconductor assembly according to the third embodiment of the present invention. The semiconductor assembly 350 is similar to that illustrated in FIG. 26, except that the routing circuitry 50 further laterally extends onto the electrical isolator 30 to provide a thermal pad 51 between the electrical isolator 30 and the semiconductor device 71. In this illustration, the thermal pad 51 is electrically connected to the base board 10 through the vertical connecting elements 20 for ground connection.

### Embodiment 4

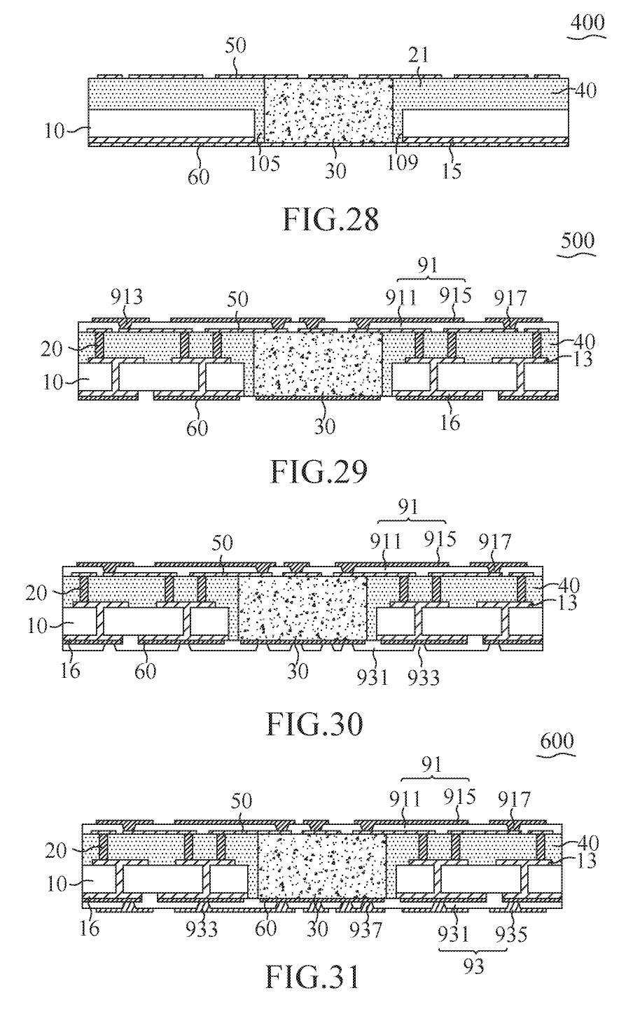

FIG. 28 is a cross-sectional view of a wiring board with no vertical connecting elements embedded in the molding compound in accordance with the fourth embodiment of the present invention.

For purposes of brevity, any description in Embodiments above is incorporated herein insofar as the same is applicable, and the same description need not be repeated.

The wiring board 400 is similar to that illustrated in FIG. 11, except that no top wiring layer is provided at the top side of the base board 10 and no vertical connecting element is deposited on the top side of the base board 10. In this embodiment, the placement accuracy of the electrical isolator 30 is provided by the interior sidewalls 109 of the base board 10. As a result, the electrical isolator 30 can be accurately confined at a predetermined location, with the peripheral edges of the electrical isolator 30 in close proximity to the interior sidewalls 109 of the through opening 105 of the base board 10. Additionally, the base board 10 also may be a single-layer structure and made of a composite material such as FR-4 (a woven fiberglass cloth soaked with an epoxy resin binder that is flame resistant), bismaleimide triazine (BT) resin, molding compound, ceramic, glass, plastic, metal or other materials.

### Embodiment 5

FIG. 29 is a cross-sectional view of a wiring board having a top buildup circuitry electrically connected to the bottom wiring layer of the base board in accordance with the fifth embodiment of the present invention.

The wiring board 500 is similar to that illustrated in FIG. 22, except that it further includes a top buildup circuitry 91. In this illustration, the top buildup circuitry 91 is a multi-layered buildup circuitry and includes a top dielectric layer 911 and top conductive traces 915. The top dielectric layer 911 contacts and covers and extends laterally on the electrical isolator 30, the molding compound 40 and the routing circuitry 50 from above. The top conductive traces 915 laterally extend on the top dielectric layer 911 and include metallized vias 917 in the top dielectric layer 911. As a result, the top buildup circuitry 91 is electrically connected to the routing circuitry 50 and thermally conductible to the electrical isolator 30 through the metallized vias 917 in contact with the routing circuitry 50.

### Embodiment 6

FIGS. 30-31 are schematic views showing a method of making a wiring board having top and bottom buildup circuitries in accordance with the sixth embodiment of the present invention.

For purposes of brevity, any description in Embodiments above is incorporated herein insofar as the same is applicable, and the same description need not be repeated.

FIG. 30 is a cross-sectional view of the structure of FIG. 29 further provided with a bottom dielectric layer 931 on the bottom plated layer 60 and via openings 933 in the bottom dielectric layer 931. The bottom dielectric layer 931 contacts and covers and extends laterally on the bottom plated layer 60 from below. The via openings 933 extend through the bottom dielectric layer 931 and are aligned with selected portions of the bottom plated layer 60.

Referring now to FIG. 31, bottom conductive traces 935 are formed on the bottom dielectric layer 931 by metal deposition and metal patterning process. The bottom conductive traces 935 extend from the bottom plated layer 60 in the downward direction, fill up the via openings 933 to form metallized vias 937 in direct contact with bottom plated layer 60, and extend laterally on the bottom dielectric layer 931. At this stage, a bottom buildup circuitry 93 is formed under the base board 10 and the electrical isolator 30 and electrically coupled to the bottom wiring layer 16 of the base board 10 and thermal conductible to the electrical isolator 30 through the metallized vias 937. In this illustration, the bottom buildup circuitry 93 is a multi-layered buildup circuitry and includes a bottom dielectric layer 931 and bottom conductive traces 935.

Accordingly, as shown in FIG. 31, a wiring board 600 is accomplished and includes a base board 10, vertical connecting elements 20, an electrical isolator 30, a molding compound 40, a routing circuitry 50, a bottom plated layer 60, a top buildup circuitry 91 and the bottom buildup circuitry 93. In this embodiment, the combination of the base board 10, the vertical connecting elements 20 and the routing circuitry 50 provides electrical connection between the top buildup circuitry 91 and the bottom buildup circuitry 93 so as to offer the wiring board 600 with stacking capability. Additionally, the metallized vias 917 of the top buildup circuitry 91 and the metallized vias 937 of the bottom buildup circuitry 97 can serve as heat pipes for thermal dissipation.

As illustrated in the aforementioned embodiments, a distinctive wiring board is configured to have an electrical isolator and a base board and exhibit improved reliability. Preferably, the wiring board mainly includes an electrical isolator, a base board, a molding compound and a routing circuitry, wherein (i) the electrical isolator is inserted into a through opening of the base board and has a larger thickness than the base board; (ii) the molding compound covers a top side of the base board and sidewalls of the electrical isolator and fills up a gap between peripheral edges of the electrical isolator and interior sidewalls of the through opening; and (iii) the routing circuitry is deposited on an exterior surface of the molding compound and optionally further laterally extends onto a top surface of the electrical isolator.

Optionally, the wiring board may further include a plurality of vertical connecting elements, wherein (i) the vertical connecting elements each have a top side not covered by the molding compound and a bottom side in contact with and electrically coupled to top contact pads of the base board, (ii) the molding compound covers sidewalls of the vertical connecting elements, and (iii) the routing circuitry contacts and are electrically coupled to the top side of the vertical connecting elements.

The electrical isolator can provide a platform for chip attachment, whereas the optional vertical connecting elements can serve as signal vertical transduction pathway or provide ground/power plane for power delivery and return. Specifically, the electrical isolator is made of a thermally conductive and electrically insulating material and typically has high elastic modulus and low coefficient of thermal expansion (for example, 2×10⁻⁶ K⁻¹ to 10×10⁻⁶ K⁻¹). As a result, the electrical isolator, having CTE matching a semiconductor device to be assembled thereon, provides a CTE-compensated platform for the semiconductor device, and thus internal stresses caused by CTE mismatch can be largely compensated or reduced. Further, the electrical isolator also provides primary heat conduction for the semiconductor device so that the heat generated by the semiconductor device can be conducted away.

The base board can be used for the placement accuracy of the electrical isolator or/and serve as a platform for the deposition of the vertical connecting elements. Specifically, the base board may be a metal plate or a single-layered or multi-layered structure having an insulating layer, and have interior sidewalls as an alignment guide for the placement of the electrical isolator. The interior sidewalls of the base board can be laterally aligned with four lateral surfaces of the electrical isolator to define an area with the same or similar topography as the electrical isolator and prevent the lateral displacement of the electrical isolator. As a result, the interior sidewalls of the base board in close proximity to the peripheral edges of the electrical isolator can provide placement accuracy for the electrical isolator. Also/or, the base board may be used to enhance routing flexibility of the wiring board. For instance, the base board may have a top wiring layer at its top side to provide additional routing in electrical connection with the routing circuitry on the molding compound through the vertical connecting elements embedded in the molding compound. Optionally, the base board may further have a plurality of bottom contact pads at its bottom side thereof electrically coupled to the top contact pads thereof. Accordingly, the wiring board can provide electrical contacts at its top and bottom sides. In a preferred embodiment, the bottom contact pads are provided by a bottom wiring layer at the bottom side of the base board, and electrically coupled to the top wiring layer through metallized through vias in the base board.

The molding compound can be bonded to the electrical isolator and the base board by paste printing, compressive molding, transfer molding, liquid injection molding, spin coating, or other suitable methods. Preferably, the molding compound has an elastic modulus larger than 1.0 GPa, a linear coefficient of thermal expansion in a range from about 5×10⁻⁶ K⁻¹ to about 15×10⁻⁶ K⁻¹, and a thickness in a range of 0.05 to 1 mm where it contacts the base board. Additionally, for sufficient thermal conductivity and suitable viscosity, the molding compound may include thermally conductive fillers in a range of 10 to 90% by weight. For instance, the thermally conductive fillers may be made of aluminum nitride (AlN), aluminum oxide, silicon carbide (SiC), tungsten carbide, boron carbide, silica or the like and preferably has relatively high thermal conductivity, high electrical resistance, and a relatively low CTE. Accordingly, the molding compound would exhibit improved heat dissipation performance, electrical isolation performance and shows inhibition of delamination or cracking of the routing circuitry or interfaces due to low CTE. Additionally, the maximum particle size of the thermally conductive fillers may be 25 μm or less.

The routing circuitry on the exterior surface of the molding compound may further extend onto the top surface of the electrical isolator. As a result, the routing circuitry can provide electrical contacts on the electrical isolator to allow a semiconductor device to be flip-chip attached on the electrical isolator, or provide a thermal pad on the electrical isolator for a semiconductor device face-up mounted thereon. The routing circuitry can be formed by metal deposition using photolithographic process. Preferably, the routing circuitry is deposited by a sputtering process and then an electrolytic plating process.

The vertical connecting elements can be formed to be electrically connected to the base board before or after provision of the molding compound. Examples of the vertical connecting elements include, but are not limited to metal posts, conductive balls, bonding wires, metal filled vias or their combination. More specifically, the vertical connecting elements can have a top side in contact with the routing circuitry and a bottom side in contact with the top contact pads of the base board to provide electrical connection between the routing circuitry and the base board. For instance, the vertical connecting elements may contact and be electrically coupled to selected portions of the top wiring layer of the base board. As a result, two-layered routing, including the top wiring layer and the routing circuitry, can enhance routing flexibility of the wiring board.

For further routing, the wiring board may further include a top buildup circuitry over the routing circuitry or/and a bottom buildup circuitry under the bottom surface of the electrical isolator and the bottom side of the base board. The top buildup circuitry can be provided to cover the top surface of the electrical isolator and the exterior surface of the molding compound and be electrically coupled to the routing circuitry and thermally conductible to the electrical isolator. The bottom buildup circuitry can be provided to cover the bottom surface of the electrical isolator and the bottom side of the base board and be electrically coupled to the bottom contact pads of the base board and thermally conductible to the electrical isolator. Preferably, the top buildup circuitry and the bottom buildup circuitry are multi-layered buildup circuitries without a core layer, and each includes at least one dielectric layer and conductive traces that fill up via openings in the dielectric layer and extend laterally on the dielectric layer. The dielectric layer and the conductive traces are serially formed in an alternate fashion and can be in repetition when needed. Accordingly, the top buildup circuitry and the bottom buildup circuitry can be thermally conductible to the electrical isolator and be electrically coupled to the routing circuitry and the base board through metallized vias, respectively. The outmost conductive traces of the top and bottom buildup circuitries can respectively accommodate conductive joints, such as solder balls or bonding wires, for electrical communication and mechanical attachment with an assembly, an electronic device or others.

The present invention also provides a semiconductor assembly in which a semiconductor device such as chip is mounted over the top surface of the electrical isolator of the aforementioned wiring board and electrically coupled to the routing circuitry. Specifically, the semiconductor device can be electrically connected to the wiring board using various using a wide variety of connection media including conductive bumps (such as gold or solder bumps) on the routing circuitry of the wiring board or bonding wires attached to the routing circuitry of the wiring board. When the wiring board includes the top buildup circuitry, the semiconductor device can be disposed over the top buildup circuitry and aligned with the electrical isolator, and electrically coupled to the top buildup circuitry.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction. For instance, the bottom buildup circuitry covers the electrical isolator, the molding compound and the base board in the downward direction regardless of whether another element such as the bottom plated layer is between the bottom buildup circuitry and the electrical isolator, between the bottom buildup circuitry and the molding compound, and between the bottom buildup circuitry and the base board.

The phrases “mounted on” and “attached on” include contact and non-contact with a single or multiple support element(s). For instance, the semiconductor device can be attached on the electrical isolator regardless of whether the semiconductor device is separated from the electrical isolator by a the routing circuitry and the conductive bumps.

The phrase “aligned with” refers to relative position between elements regardless of whether elements are spaced from or adjacent to one another or one element is inserted into and extends into the other element. For instance, the interior sidewalls of the base board are laterally aligned with the peripheral edges of the electrical isolator since an imaginary horizontal line intersects the interior sidewalls of the base board and the peripheral edges of the electrical isolator, regardless of whether another element is between the interior sidewalls of the base board and the peripheral edges of the electrical isolator and is intersected by the line, and regardless of whether another imaginary horizontal line intersects the peripheral edges of the electrical isolator but not the interior sidewalls of the base board or intersects the interior sidewalls of the base board but not the peripheral edges of the electrical isolator. Likewise, in a preferred embodiment, some metallized vias of the top buildup circuitry and the bottom buildup circuitry are aligned with the electrical isolator.

The phrase “in close proximity to” refers to a gap between elements not being wider than the maximum acceptable limit. As known in the art, when the gap between the peripheral edges of the electrical isolator and the interior sidewalls of the base board is not narrow enough, the electrical isolator may not be accurately confined at a predetermined location. The maximum acceptable limit for a gap between the peripheral edges of the electrical isolator and the interior sidewalls of the base board can be determined depending on how accurately it is desired to dispose the electrical isolator at the predetermined location. Thereby, the descriptions “the peripheral edges of the electrical isolator in close proximity to the interior sidewalls of the through opening” and “the interior sidewalls of the base board in close proximity to the peripheral edges of the electrical isolator” mean that the gap between the peripheral edges of the electrical isolator and the interior sidewalls of the through opening is narrow enough to prevent the location error of the electrical isolator from exceeding the maximum acceptable error limit. For instance, the gaps in between the peripheral edges of the electrical isolator and the interior sidewalls of the through opening may be in a range of about 25 to 100 microns.

The phrases “electrical connection”, “electrically connected” and “electrically coupled” refer to direct and indirect electrical connection. For instance, the semiconductor device can be electrically connected to the routing circuitry by the top buildup circuitry but does not contact the routing circuitry.

The wiring board according to the present invention has numerous advantages. The electrical isolator provides CTE-compensated platform for the attachment of a semiconductor device and also establish a heat dissipation pathway for spreading out the heat generated by the semiconductor device. The molding compound provides mechanical support and serves as a spacer between the routing circuitry and the base board and between the electrical isolator and the optional vertical connecting elements. The routing circuitry provides horizontal electrical routing of the wiring board, whereas the optional vertical connecting elements provide vertical electrical routing to electrically connect the routing circuitry on the molding compound and another horizontal electrical routing provided in the base board. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board, comprising:
a base board that includes a top side, a bottom side, a plurality of top contact pads at the top side and a through opening, wherein the through opening has interior sidewalls extending from the top side to the bottom side;
an electrical isolator disposed in the through opening of the base board, wherein the electrical isolator has a bottom surface substantially coplanar with the bottom side of the base board and a thickness greater than that of the base board;
a molding compound that covers the top side of the base board and extends into a gap between peripheral edges of the electrical isolator and the interior sidewalls of the through opening, wherein the molding compound has an exterior surface substantially coplanar with a top surface of the electrical isolator;
a routing circuitry disposed on the exterior surface of the molding compound; and
a plurality of vertical connecting elements disposed on the top side of the base board and embedded in the molding compound and electrically coupled to the routing circuitry and the top contact pads of the base board.

2. The wiring board of claim 1, wherein the routing circuitry further laterally extends onto the top surface of the electrical isolator.

3. The wiring board of claim 1, wherein the top contact pads are selected portions of a top wiring layer at the top side of the base board.

4. The wiring board of claim 1, wherein the base board further includes a plurality of bottom contact pads at the bottom side thereof and electrically coupled to the top contact pads through metallized through vias in the base board.

5. The wiring board of claim 1 further includes a bottom plated layer at the bottom surface of the electrical isolator and thermally conductible to the bottom side of the base board.

6. The wiring board of claim 1, wherein the electrical isolator is a thermally conductive and electrically insulating ceramic slug.

7. The wiring board of claim 1, wherein the vertical connecting elements are made of a metal selected from the group consisting of Cu, Ti, Ni, Au, Ag, Sn, and Sn alloy, wherein the Sn alloy contains Ag, Cu, Bi, or combinations thereof.

8. The wiring board of claim 1, further comprising a top buildup circuitry disposed over and electrically coupled to the routing circuitry and thermally conductible to the electrical isolator.

9. The wiring board of claim 4, further comprising a bottom buildup circuitry disposed under the bottom surface of the electrical isolator and the bottom side of the base board and electrically coupled to the bottom contact pads of the base board and thermally conductible to the electrical isolator.

10. A semiconductor assembly, comprising:
the wiring board of claim 1; and
a semiconductor device that is mounted over the top surface of the electrical isolator and electrically coupled to the routing circuitry.

11. The semiconductor assembly of claim 10, wherein the semiconductor device is electrically coupled to the routing circuitry through bonding wires.

12. The semiconductor assembly of claim 10, wherein the routing circuitry further laterally extends onto the top surface of the electrical isolator, and the semiconductor device is electrically coupled to the routing circuitry through conductive bumps.

13. The semiconductor assembly of claim 10, wherein the base board further includes a plurality of bottom contact pads at the bottom side thereof electrically coupled to the top contact pads.

14. The semiconductor assembly of claim 10, wherein the wiring board further comprises a top buildup circuitry disposed over and electrically to the routing circuitry and thermally conductible to the electrical isolator, and the semiconductor device is disposed over the top buildup circuitry and electrically coupled to the routing circuitry through the top buildup circuitry.

15. The semiconductor assembly of claim 13, wherein the wiring board further comprises a bottom buildup circuitry disposed under the bottom surface of the electrical isolator and the bottom side of the base board and electrically coupled to the bottom contact pads of the base board and thermally conductible to the electrical isolator.

16. A method of making a wiring board having electrical isolator incorporated therein, the method comprising steps of:
providing a base board having a top side, a bottom side and a through opening, wherein the through opening has interior sidewalls extending from the top side and the bottom side;
inserting an electrical isolator into the through opening of the base board, with peripheral edges of the electrical isolator in close proximity to the interior sidewalls of the through opening and a bottom surface of the electrical isolator substantially coplanar with the bottom side of the base board, wherein the electrical isolator has a thickness larger than that of the electrical isolator;
providing a molding compound on the top side of the base board and into a gap between the peripheral edges of the electrical isolator and the interior sidewalls of the through opening, wherein the molding compound has an exterior surface substantially coplanar with a top surface of the electrical isolator; and
forming a routing circuitry on the exterior surface of the molding compound.

17. The method of claim 16, further comprising a step of forming a plurality of vertical connecting elements on the top side of the base board, wherein the base board includes a plurality of top contact pads at the top side thereof, and the vertical connecting elements are electrically coupled to the routing circuitry and the top contact pads of the base board.

18. The method of claim 16, wherein the routing circuitry further laterally extends onto the top surface of the electrical isolator.

19. The method of claim 17, wherein the base board further includes a plurality of bottom contact pads at the bottom side thereof electrically coupled to the top contact pads.

20. The method of claim 16, wherein the step of forming the routing circuitry on the molding compound includes a sputtering process.

21. The method of claim 16, further comprising a step of forming a top buildup circuitry on the routing circuitry, wherein the top buildup circuitry is electrically coupled to the routing circuitry and thermally conductible to the electrical isolator.

22. The method of claim 19, further comprising a step of forming a bottom buildup circuitry under the bottom surface of the electrical isolator and the bottom side of the base board and electrically coupled to the bottom contact pads of the base board and thermally conductible to the electrical isolator.
